(19) United States
(12) Patent Application Publication
(10) Pub. No.: US 2023/0353092 A1
(43) Pub. Date: Nov. 2, 2023

(54) SEMICONDUCTOR SWITCHES FOR ANALOG SIGNALS WITH IMPROVED LINEAR RESPONSE

(71) Applicants: Shaoxing Yuanfang Semiconductor Co., Ltd., Shaoxin (CN); Spirit Semiconductor Limited, Reading (GB)

(72) Inventors: Georgios Bilionis, Reading (GB); Sebastian Diebold, Pangbourne (GB)

(21) Appl. No.: 17/663,215

(22) Filed: May 13, 2022

Related U.S. Application Data
(60) Provisional application No. 63/363,814, filed on Apr. 29, 2022.

(51) Int. Cl. H03B 5/12

(52) U.S. Cl. CPC H03B 5/1293; H03B 5/1265; H03B 5/1243; H03B 2201/0208

(57) ABSTRACT

An aspect of the present disclosure improves the linearity of a semiconductor switch. In an embodiment, a capacitor providing variable capacitance is provided between an input terminal and an output terminal of the switch, which results in such a benefit. According to another aspect, the capacitor is realized by multiple varactors connected in series between the input terminal and the output terminal. A biasing network is designed to cause a respective desired voltage to be applied across each varactor for obtaining the variable capacitance.

### PRIORITY CLAIM

The present patent application is related to and claims the benefit of priority to the co-pending US provisional patent application entitled, “Linearity Enhancement in High Power RF switches”, Ser. No. 63/363,814, Filed: 29 Apr. 2022, which is incorporated in its entirety herewith to the extent not inconsistent with the description herein.

### BACKGROUND

### Technical Field

Embodiments of the present disclosure relate generally to semiconductor switches, and more specifically to improving a linear response desirable of such switches.

### Related Art

A switch refers to a component which either passes through or blocks a signal between two of its terminals. Switches are often fabricated using semiconductor material and such switches are referred to as semiconductor switches. Semiconductor switches are frequently used with analog signals, in particular Radio Frequency (RF) signals, and the corresponding switches may be referred to as RF switches, which find application in several areas such as transmitters, receivers, phased arrays, instrumentation equipment, etc.

It is generally desirable that a switch provide as linear a response as possible in the entire range of input powers the switch is expected to operate with. Linearity implies the non-existence of harmonics in the output spectrum and manifests as a straight line relationship when the output power is plotted against the input power on a graph, as is well known in the relevant arts.

Aspects of the present disclosure are directed to improving the linearity of semiconductor switches.

### BRIEF DESCRIPTION OF THE VIEWS OF DRAWINGS

Example embodiments of the present disclosure will be described with reference to the accompanying drawings briefly described below.

FIG. 1 is a circuit diagram of a semiconductor switch used to illustrate the general requirement of linearity in combination with FIG. 2.

FIG. 2 is a graph used to illustrate non-linear effects including IP3 in a device such as a switch.

FIG. 3 is a circuit diagram of an RF switch in an embodiment of the present disclosure.

FIG. 4 is a graph showing IP3 values versus input power of a switch with and without the linearization technique of the present disclosure.

FIG. 5 is a circuit diagram of a switch stack in an embodiment of the present disclosure.

FIG. 6 is a circuit diagram of an SPDT switch in an embodiment of the present disclosure.

FIG. 7 is a block diagram showing the implementation details of an example device/system in an embodiment of the present disclosure.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

An aspect of the present disclosure improves the linearity of a semiconductor switch. In an embodiment, a capacitor providing variable capacitance is provided between an input terminal and an output terminal of the switch, which results in such a benefit. The variable capacitance introduces a non-linearity that counters the non-linearity caused by parasitic elements such as a parasitic capacitance.

According to another aspect, the capacitor is realized by multiple varactors connected in series between the input terminal and the output terminal. A biasing network is designed to cause a respective desired voltage to be applied across each varactor for obtaining the variable capacitance.

According to another aspect, the biasing network includes a first set of impedance elements to divide a voltage across the first terminal and the second terminal, wherein the division causes a corresponding fraction of the voltage to be provided at a respective junction of each pair of impedance elements. The biasing network also includes a second set of impedance elements, wherein each impedance element of the second set of impedance elements is coupled between a corresponding junction of a pair of varactors on one side and the respective junction of each pair of impedance elements.

Several aspects of the present disclosure are described below with reference to examples for illustration. However, one skilled in the relevant art will recognize that the disclosure can be practiced without one or more of the specific details or with other methods, components, materials and so forth. In other instances, well known structures, materials, or operations are not shown in detail to avoid obscuring the features of the disclosure. Furthermore, the features/aspects described can be practiced in various combinations, though only some of the combinations are described herein for conciseness.

### 2. Linearity Requirement in Switches

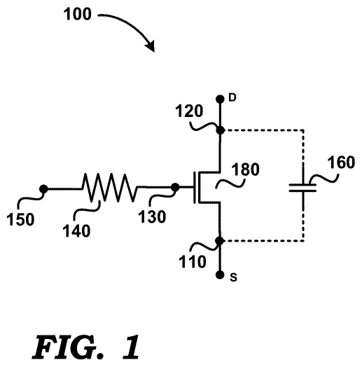

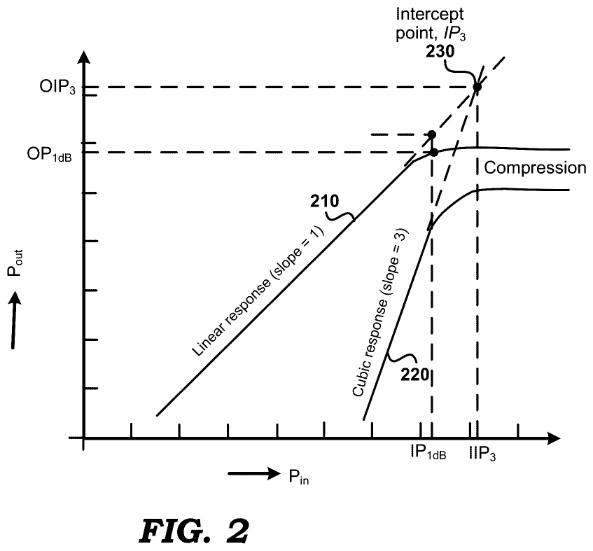

FIG. 1 is a circuit diagram of a semiconductor switch used to illustrate the general requirement of linearity in combination with FIG. 2. The semiconductor switch is described as being a Radio Frequency (RF) switch merely for illustration. However, other frequencies of signals can be switched in alternative embodiments without departing from the scope and spirit of several aspects of the present disclosure, as will be apparent to a skilled practitioner by reading the disclosure provided herein.

RF switch 100 is shown containing transistor 180 and an optional resistor 140, with capacitance 160 representing the parasitic capacitance (intrinsic to the construction of transistor 180) between source terminal 110 and drain terminal 120. It is to be understood that there may be other parasitic components like capacitances also, for example, between gate terminal 130 and source terminal 110, and gate terminal 130 and drain terminal 120, but not shown in the interest of conciseness. Transistor 180 provides a low impedance path (conductive) between source terminal 110 and drain terminal 120 upon application of one voltage level at terminal 150, and a high impedance path (non-conductive) path between the same terminals upon application of another voltage level at terminal 150. The specific magnitudes of such voltage may be determined based on various parameters (such as threshold voltage Vt between the gate and source terminals) of transistor 180, as is well known in the relevant arts. Transistor 180 can be implemented as a field effect transistor (FET), for example as a MOSFET.

Thus in operation, an RF signal is applied as input at one of source terminal 110 and drain terminal 120 and the output signal is available at the other one of the two terminals. A corresponding voltage is applied at node 150 to open or close RF switch 100, thereby blocking or passing through the input signal as output signal.

The graph of FIG. 2 depicts the output power Po versus input power Pin relationship with respect to the input signal and output signals of switch 100. Line 210 represents the input-output relationship for first order components of the signals, with a linear response in operational range up to the start of compression, from which level gain compression starts to occur.

Ideally the response of RF switch 100 should be a straight line, i.e., linear, as depicted by the segment up to the start of compression exhibited by line 210. However, due to the non-linear response of switch 100 resulting due to parasitic capacitance 160 and various other factors, the output of switch 100 contains higher order components in the output, which is undesirable.

Line 220 quantifies the input-output relationship for third order intermodulation components in the input and output signals. A key parameter of interest, which quantifies the extent of linearity of switch 100 is IP3 (third-order intercept point), which is the point (230) at which the extrapolated (shown by dotted portion) fundamental component power curve (210) meets the extrapolated third order intermodulation component power curve (220). In general, it is desirable that magnitude of IP3 (and thus point 230) should be as high as possible, implying a higher degree of linearity. That is, higher the output at the intercept, the better the linearity. The application environment specifies IP3 type of parameters indicating the desired degree of linearity. Various other parameters are also used to quantify non-linearity.

Aspects of the present disclosure operate to improve the linearity of semiconductor switches by countering, at least partially, the impact of parasitic capacitance 160, etc., as described below with examples.

### 3. RF Switch with Improved Linearity

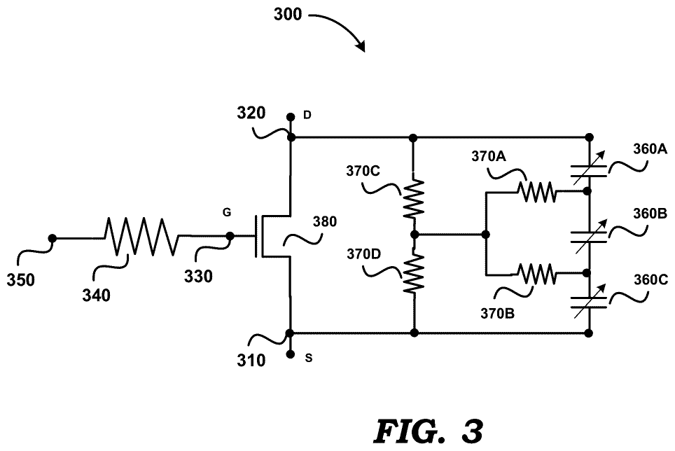

FIG. 3 is a circuit diagram of RF switch 300 in an embodiment of the present disclosure. Resistor 340 and transistor 380 along with associated terminals 310, 320, 330 and 350 correspond to, and operate similar to corresponding components and terminals in FIG. 1, and are not described again in the interest of conciseness.

The manner in which the remaining components resistors 370A-370D and varactors 360A-360C operate to improve the linearity of RF switch 300 is described below. However, it should be understood that only representative number/type of components are shown in FIG. 3 for conciseness. Different equivalent components and/or more or fewer of each of those components can be employed as suited in corresponding environments, without departing from the scope and spirit of several aspects of the present disclosure, as will be apparent to a skilled practitioner by reading the disclosure provided herein.

The stack of varactors 360A-360C, provided external to transistor 380, together with biasing network constituted of resistors (examples of impedances) 370A-370D provide a variable capacitance between source terminal 310 and drain terminal 320. Specifically, each varactor in the varactor stack (between drain and source terminals) offers a non-linear response determined by the voltage applied across the varactor. Thus, the total added capacitance across source and drain terminals is variable and therefore introduces a deliberate non-linearity (as against non-linearity due to any inherent parasitic elements. The non-linear behaviour of transistor 380 (due to parasitic capacitance across the drain and source terminals) is minimized by the non-linear response of the varactor stack.

In an embodiment, each varactor is implemented using a MOS transistor. The source and drain terminals of the MOS transistor used to implement each varactor are shorted, and the two terminals of the resulting capacitor are the gate terminal of the MOS transistor and the source (or drain) terminal of the MOS transistor. However, in other embodiments other types of varactors, such as reverse-biased diodes along with a biasing network, can instead be used. The number of varactors generally depends on the input power to switch 300. It should be understood that the total gate width and gate length of each varactor also can contribute to the generated non-linearity. Thus, an appropriate number of varactors of appropriate gate width/length may be employed depending on the magnitude specification of input power.

Resistors 370A-370D operate to provide a DC voltage at each terminal of the varactors, thereby avoiding any floating nodes in the varactor stack and resistor network. In addition, the resistor values control the extent of non-linearity introduced by the varactors. In effect, the resistors cause self-biasing of the varactors.

It may be observed that the aggregate response (non-linearity) of the varactor stack counters the non-linearity caused by the parasitic capacitance (akin to 160 of FIG. 1). Specifically, the phase of the current through the varactor stack is 180 degrees (or close to 180 degrees) shifted with respect to the current through the parasitic capacitor (between terminals 310 and 320), thereby canceling the non-linear effects due to the parasitic capacitor, and thus improving the linearity of RF switch 300.

The use of multiple numbers of small-valued non-linearities (i.e., multiple varactors) enables relaxing technology limitations on each varactor's physical parameters/dimensions. Furthermore, such an approach does not suffer from power limitations (large voltage swings) at the varactor pins. The breakdown voltage of the structure (switch 300) is defined primarily by the breakdown voltage of transistor 380. Switch 300 can be fabricated using (among several manufacturing technologies) silicon-on-insulator (SOI) manufacturing technology or bulk-CMOS manufacturing technology. Thus, transistor 380 may be constructed consistent with the manufacturing technology. When using SOI technology, the body node of transistor 380 can be left floating or coupled to a suitable node such as gate 330.

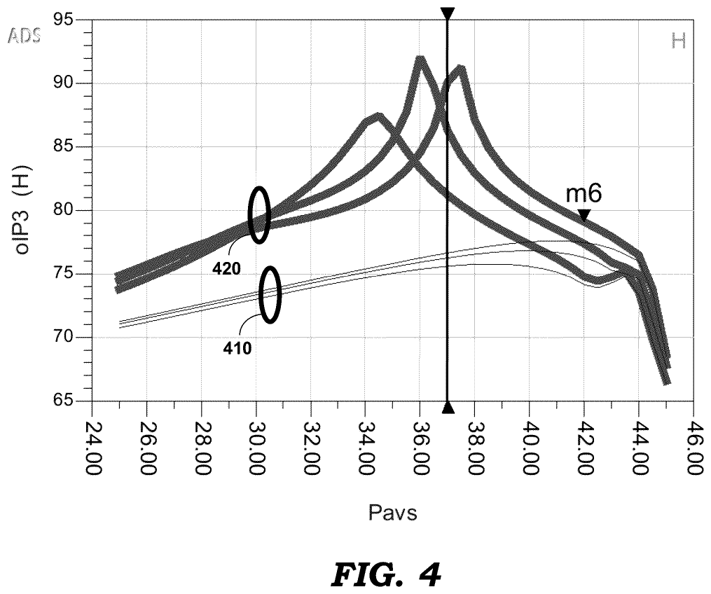

FIG. 4 is a graph showing IP3 values versus input power with (marked as 420) and without (marked as 410) the linearization technique described above for three different temperatures. It may be observed that IP3 values are higher when the linearization technique of the present disclosure is employed.

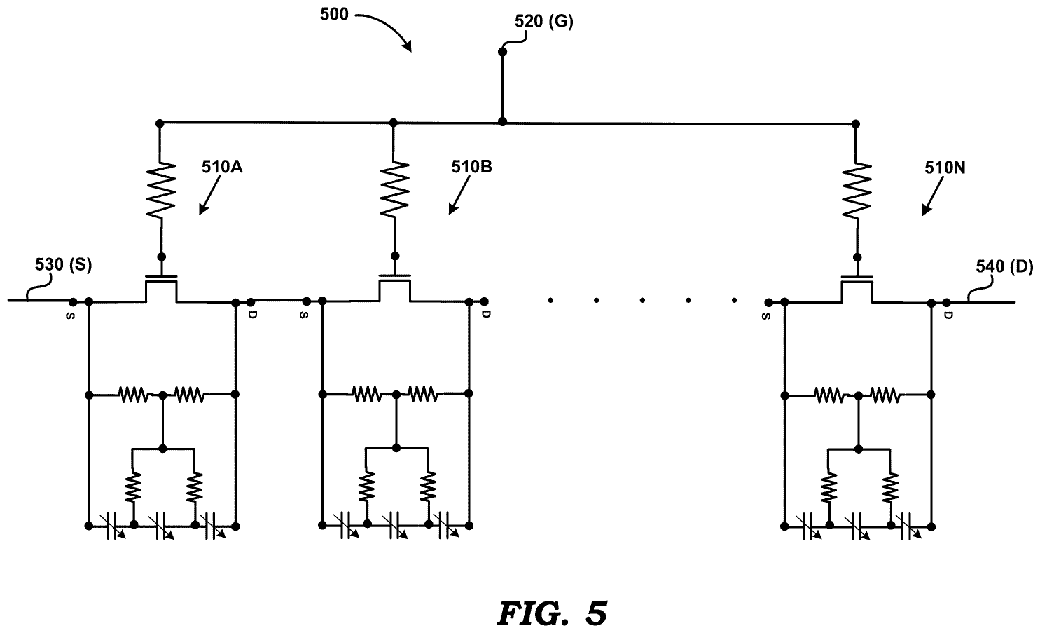

FIG. 5 is a diagram showing a series connection of multiple switches such as switch 300 to form a switch stack. In FIG. 5, switch stack 500 is shown with switches 510A through 510N, each implemented as switch 300 of FIG. 3. Terminals 520, 530 and 540 respectively represent the gate, source and drain terminals of the stack. Such stacking may be used when higher power levels or voltages need to be supported by an RF switch.

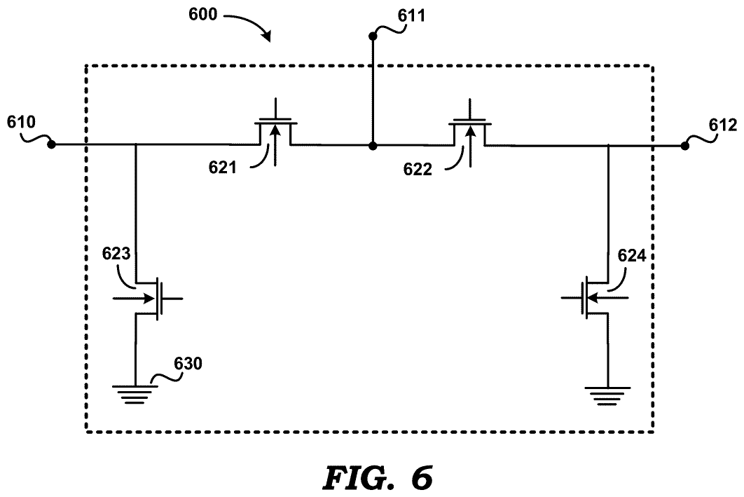

FIG. 6 is a diagram showing an SPDT (single pole, double throw) switch 600 built using multiple one of switch 300. SPDT switch 600 is used to connect terminal 611 (pole) to either terminal 610 (throw 1) or terminal 612 (throw2). Each of switches 621-624 may represent one switch (such as switch 300) or a stack of switches (such as stack 500). Switch 621 is in the path between terminals 611 and 610. Switch 623 is present in a shunt arm between terminals 610 and ground (630/constant reference potential). Similarly, switch 622 is in the path between terminals 611 and 612. Switch 624 is present in a shunt arm between terminals 612 and ground (630). When SPDT switch 600 is to connect terminal 610 to terminal 611, switches 621 and 624 are switched ON, while switches 622 and 623 are switched OFF. When SPDT switch 600 is to connect terminal 612 to terminal 611, switches 621 and 624 are switched OFF, while switches 622 and 623 are switched ON.

It should be appreciated that SPDT is merely an example component in which the features of the invention can be implemented. However, aspects of the present disclosure can be implemented in other components/devices such as SPSTs (single pole single throw), SPxTs (single pole and X number of throw), where x=1 . . . n (integer), as will be apparent to a skilled practitioner by reading the disclosure provided herein.

An RF switch implemented as described above can be used in a device or system as described briefly next.

### 4. Device/System

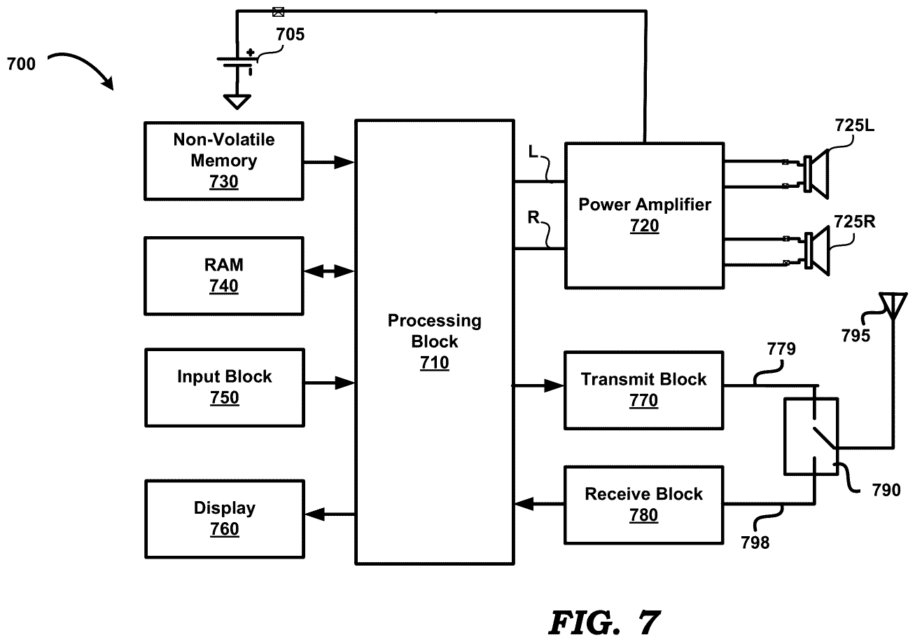

FIG. 7 is a block diagram showing the implementation details of an example device/system in an embodiment of the present disclosure. Mobile phone 700 is shown containing battery 705, processing block 710, power amplifier 720, speakers 725L and 725R, non-volatile memory 730, random access memory (RAM) 740, input block 750, display 760, transmit block 770, receive block 780, switch 790 and antenna 795. The specific components/blocks of mobile phone 700 are shown merely by way of illustration. However, mobile phone 700 may contain more or fewer components/blocks.

Battery 705 represents an unregulated power supply, used to power the various blocks of mobile phone 700. Although not indicated, one or more of blocks other than power amplifier 720 may receive power for operation from battery 705 via corresponding regulated power supplies (not shown, but which could be, for example, implemented as linear regulators).

In FIG. 7, the signals on paths L and R are assumed to be digital signals representing the left and right audio channels of an audio system. Power amplifier 720 generates corresponding power-amplified outputs to drive respective speakers 725L and 725R. Although power amplifier 720 is noted as receiving input signals from processing block 710 in digital form, in another embodiment power amplifier 720 receives input signals from processing block 710 in analog form, the digital to analog conversion of the corresponding digital signals being performed within a digital to analog converter within processing block.

Processing block 710 may store speech and/or audio signals that are represented by the signal provided as input (whether in analog from or digital form) to power amplifier 720 on paths L and R in the form of files in non-volatile memory 730. Such files may be input to mobile phone 700 via input block 750 or received via receive block 780 and antenna 795.

Input block 750 represents one or more input devices used to provide user inputs to mobile phone 700. Input block 750 may include a keypad, microphone, etc. Display 760 represents a display screen (e.g., liquid crystal display) to display images generated by processor 710.

Antenna 795 operates to receive from and transmit to a wireless medium, corresponding wireless signals carrying speech and/or audio. Switch 790 represents an SPDT switch, and may be controlled by processing block 710 (connection not shown) to connect antenna 795 either to receive block 780 via path 798, or to transmit block 770 via path 779, depending on whether mobile phone 700 is to receive or transmit wireless signals. Switch 790 can be implemented as SPDT switch 600 as described in detail above.

Transmit block 770 receives data/speech/audio (information signal in general) to be transmitted from processing block 710, generates a radio frequency (RF) signal modulated by the information signal according to corresponding standards such as GSM, CDMA, etc., and transmits the RF signal via switch 790 and antenna 795. Receive block 780 receives an RF signal bearing an information signal via switch 790, path 798 and antenna 795, demodulates the RF signal, and provides the extracted information (speech/audio/data) to processing block 710.

Non-volatile memory 730 is a non-transitory machine readable medium, and stores instructions, which when executed by processing block 710, causes mobile phone 700 to provide several features. RAM 730 is a volatile random access memory, and may be used for storing instructions and data.

### 5. Conclusion

References throughout this specification to “one embodiment”, “an embodiment”, or similar language means that a particular feature, structure, or characteristic described in connection with the embodiment is included in at least one embodiment of the present disclosure. Thus, appearances of the phrases “in one embodiment”, “in an embodiment” and similar language throughout this specification may, but do not necessarily, all refer to the same embodiment.

While in the illustrations of FIGS. 3, 5, 6 and 7, although terminals/nodes are shown with direct connections to (i.e., “connected to”) various other terminals, it should be appreciated that additional components (as suited for the specific environment) may also be present in the path, and accordingly the connections may be viewed as being “electrically coupled” to the same connected terminals.

In the instant application, the power and ground terminals are referred to as constant reference potentials.

While various embodiments of the present disclosure have been described above, it should be understood that they have been presented by way of example only, and not limitation. Thus, the breadth and scope of the present disclosure should not be limited by any of the above-described embodiments, but should be defined only in accordance with the following claims and their equivalents.

1: A semiconductor switch comprising:
a transistor having a first terminal, a second terminal and a third terminal,
said transistor to receive an input signal on said first terminal and to operate as a switch between said first terminal and said second terminal,
wherein said third terminal is operable to receive a first voltage level or a second voltage level representing respective value of a binary value,
wherein a conductive path is provided between said first terminal and said second terminal when said third terminal receives said first voltage level to pass said input signal to said second terminal, and said conductive path is absent between said first terminal and said second terminal when said third terminal receives said second voltage level to block said input signal from being passed to said second terminal; and
a capacitor of variable capacitance provided between said first terminal and said second terminal, with the magnitude of said capacitance depending on a magnitude of power of said input signal passing through said conductive path, wherein said capacitor is provided external to said transistor.

2: The switch of claim 1, wherein an analog signal is provided as said input signal at said first terminal and a corresponding output is provided at said second terminal, wherein a response of said switch is measured as a relationship of power of said output versus power of said input signal, wherein said capacitor operates to improve a linearity of said relationship.

3: The switch of claim 2, wherein said capacitor comprises a plurality of varactors connected in series between said first terminal and said second terminal.

4: The switch of claim 3, further comprising a biasing network to cause a respective desired voltage to be applied across each varactor.

5: The switch of claim 4, wherein said biasing network comprises a first set of impedance elements to divide a voltage across said first terminal and said second terminal, wherein said division causes a corresponding fraction of said voltage to be provided at a respective junction of each pair of impedance elements,
a second set of impedance elements, wherein each impedance element of said second set of impedance elements is coupled between a corresponding junction of a pair of varactors on one side and the respective junction of said each pair of impedance elements.

6: The switch of claim 5, wherein each of said impedance element comprises a corresponding resistor.

7: The switch of claim 6, wherein said analog signal is a Radio Frequency (RF) signal, said switch is an RF switch, said transistor is one of Field Effect Transistor (FET) and Metal-Oxide Semiconductor (MOS) transistor, and each of said plurality of varactors is implemented as a corresponding MOS transistor.

8: A system comprising:
a transmitter to generate a radio frequency (RF) signal;
a receiver to process another RF signal;
an antenna to transmit, on a wireless medium, said RF signal received from said transmitter, said antenna to receive said another RF signal on said wireless medium and to forward said another RF signal to said receiver; and
a single pole double throw (SPDT) switch having a pole terminal coupled to said antenna, a first throw terminal coupled to said transmitter, and a second throw terminal coupled to said receiver, said SPDT switch to couple said transmitter to said antenna during a transmit duration, said RF switch to couple said receiver to said antenna during a receive duration, said SPDT switch comprising a plurality of RF switches,
wherein an RF switch of said SPDT switch comprises:
a transistor having a first terminal, a second terminal and a third terminal,
said transistor to receive an input signal on said first terminal and to operate as a switch between said first terminal and said second terminal,
wherein said third terminal is operable to receive a first voltage level or a second voltage level representing respective value of a binary value,
wherein a conductive path is provided between said first terminal and said second terminal when said third terminal receives said first voltage level to pass said input signal to said second terminal, and said conductive path is absent between said first terminal and said second terminal when said third terminal receives said second voltage level to block said input signal from being passed to said second terminal; and
a capacitor providing variable capacitance between said first terminal and said second terminal depending on a magnitude of power passing through said conductive path, wherein said capacitor is provided external to said transistor.

9: The system of claim 8, wherein one of said RF signal and said another RF signal is provided as said input signal at said first terminal and a corresponding output is provided at said second terminal, wherein a response of said switch is measured as a relationship of power of said output versus power of said input signal, wherein said capacitor operates to improve a linearity of said relationship.

10: The system of claim 9, wherein said capacitor comprises a plurality of varactors connected in series between said first terminal and said second terminal.

11: The system of claim 10, further comprising a biasing network to cause a respective desired voltage to be applied across each varactor.

12: The system of claim 11, wherein said biasing network comprises a first set of impedance elements to divide a voltage across said first terminal and said second terminal, wherein said division causes a corresponding fraction of said voltage to be provided at a respective junction of each pair of impedance elements,
a second set of impedance elements, wherein each impedance element of said second set of impedance elements is coupled between a corresponding junction of a pair of varactors on one side and the respective junction of said each pair of impedance elements.

13: The system of claim 12, wherein each of said impedance element comprises a corresponding resistor.

14: The system of claim 13, wherein said system is a mobile phone,
wherein said transistor is one of Field Effect Transistor (FET) and Metal-Oxide Semiconductor (MOS) transistor, and each of said plurality of varactors is implemented as a corresponding MOS transistor.
